(19) United States
(12) Patent Application Publication
(10) Pub. No.: US 2013/0291926 A1
(43) Pub. Date: Nov. 7, 2013

(54) Solar Tracking Apparatus

(71) Applicant: David Matalon, Brooklyn, NY (US)

(72) Inventor: David Matalon, Brooklyn, NY (US)

(73) Assignee: MATALON ENERGY, LLC, New York, NY (US)

(21) Appl. No.: 13/461,127

(22) Filed: May 1, 2012

(51) Int. Cl. H01L 31/052

(52) U.S. Cl. 136/246

(57) ABSTRACT

A solar tracking apparatus is provided having pivoting struts located proximate the north and south sides of the collector surface. The crossed struts permit the inclination angle of the collector surface to be varied throughout the day without heavy supports. The support frame can be adapted for quick assembly, disassembly and transportation.

### BACKGROUND OF THE INVENTION

1. Field of the Invention

The invention is directed to a solar energy collection apparatus. In particular, the invention is directed to an apparatus for orienting a solar collector surface at a given inclination angle during operation to maximize the amount of solar radiation incident on the collector surface.

2. Description of the Related Art

Solar collectors, such as photovoltaic arrays, commonly referred to as “solar panels,” are frequently mounted at a fixed inclination angle with respect to the horizontal. An optimal inclination angle is set with respect to the horizontal for a given geographic location and time of year. So-called “tracking” systems are also known, whereby the inclination angle of a collector surface is varied throughout the day pursuant to a control scheme to maximize solar radiation incident on the panel. The control scheme may be based on conditions at the collector, or alternatively, time of day and location information can be programmed into the control unit so that the inclination angle of the collector varies according to the known position of the sun in the sky at a particular location and time. In either case, the panel is oriented at a more vertical orientation, facing east, in the morning and approaches a more horizontal orientation as the sun is positioned more directly overhead at midday. The collector surface may also rotate about a vertical axis from east to west (“two-axis tracking”). This technique further optimizes the amount of solar radiation incident on the collector surface.

Modes of maintaining a panel at a proper orientation, including the support systems, are disclosed in U.S. Pat. Nos. 6,563,040 and 7,888,588, for example, herein incorporated by reference. Measurement of heat and/or light produced by the sun in the proximity of the device may be used to control the position of a tracker, as disclosed in U.S. Pat. No. 8,069,849, by the inventor herein, and hereby incorporated by reference. The collectors may be put into service at the start of the day and “parked” at night according to a predetermined protocol.

With few exceptions, at least as far as terrestrial solar collectors are concerned, the collectors in the prior art with tracking capabilities are characterized by having a support member at the axis of rotation where the panel pivots from east to west. For example, if the panel is elongated, a panel or row of panels may be supported by a member running horizontally for the length of the panel along its longitudinal central axis, and the panel is caused to pivot about the elongated support member throughout the day. Alternatively, a post is provided, supporting the center of gravity of the panel, and that point of the panel is provided with an easel connection, a universal joint, or other connector, and the angle and position of the panel is varied from this point.

While there is nothing inherently wrong with the aforesaid designs, there is a limit to how collector arrays can be integrated with real estate and other structures if the support is situated at the axis of rotation of the panel. There continues to be a need for robust mounting solutions for solar collector panels, such that tracking can be used to increase the efficiency of the device, while permitting innovative mounting solutions near the end user, such as on a building roof. It would also be desirable to have a solar tracking apparatus which is readily assembled, disassembled as transported.

Thus, one object of the invention is to provide innovative mounting solutions for solar collectors by using supports on the sides of the collector surface, thereby freeing space ordinarily occupied by support members. The supporting unit according to the invention can be mounted on any flat or slanted roof, as it has a wide base that eliminates heavy and complicated supports.

### SUMMARY OF THE INVENTION

These and other objects of the invention are achieved in one aspect with a solar tracking device comprising a collector having an upward-facing surface and opposed sides. The collector surface may be, for example, a flat rectangular photovoltaic array. The tracking apparatus further comprises at least two pivot points on each of the opposed sides of the collector surface (generally the north and south sides), and base connectors equal in number to the number of pivot points. The base connectors lie in a plane, and each base connector is at a fixed position in the plane relative to the other base connectors. The base connectors may be affixed to the earth, a roof or other structure, or on a secured base or frame. Elongated struts, equal in number to the pivot points, each have a first end connected to a pivot point connector at a pivot point, and a second end connected to a respective base connector. Each pivot point connector permits rotation of each respective strut about the pivot point, and each base connector permits rotation of each respective strut about the respective base connector. The struts are arranged such that on each side of the collector, two struts connecting respective pivot point connectors and base connectors cross. Thus, for example, the pivot point further to the east on a given side of the collector surface is connected via a strut to a base connector further to the west. A drive system is provided, operatively connected to at least one strut, adapted to pivot the strut (and thus the entire connected tracking system) to vary the inclination angle of the collector. The design, operation and advantages of the tracking system will become apparent in the detailed description that follows.

### BRIEF DESCRIPTION OF THE FIGURES

FIG. 1 depicts an embodiment of a tracking apparatus according to the invention.

FIG. 2A and FIG. 2B depict an apparatus with a plurality of collector surfaces, arranged so that the same drive system orients the inclination angle of the plurality of collector surfaces.

FIG. 3 schematically illustrates the range of motion of a solar tracking apparatus according to an embodiment of the invention.

FIG. 4 schematically illustrates the motion of the solar tracking apparatus according to an embodiment of the invention, supporting a passive solar collector, such as a parabolic trough or parabolic dish.

FIG. 5 depicts an apparatus according to an embodiment of the invention wherein the base is adapted to rotate about a vertical axis.

FIG. 6 is an isometric view of a solar tracking apparatus according to the invention supporting a parabolic collector.

### DETAILED DESCRIPTION OF THE PREFERRED EMBODIMENTS

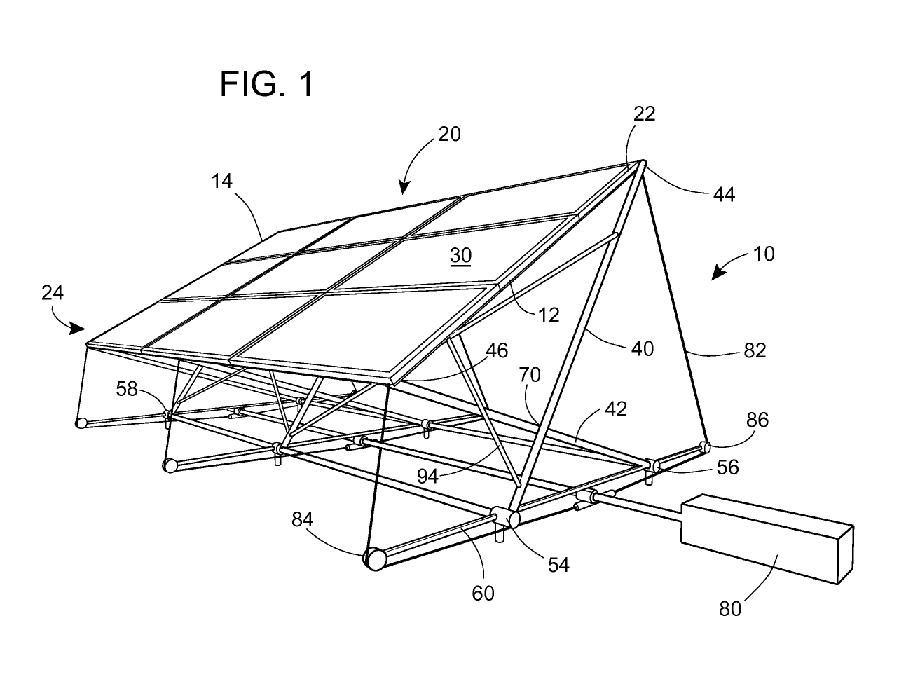

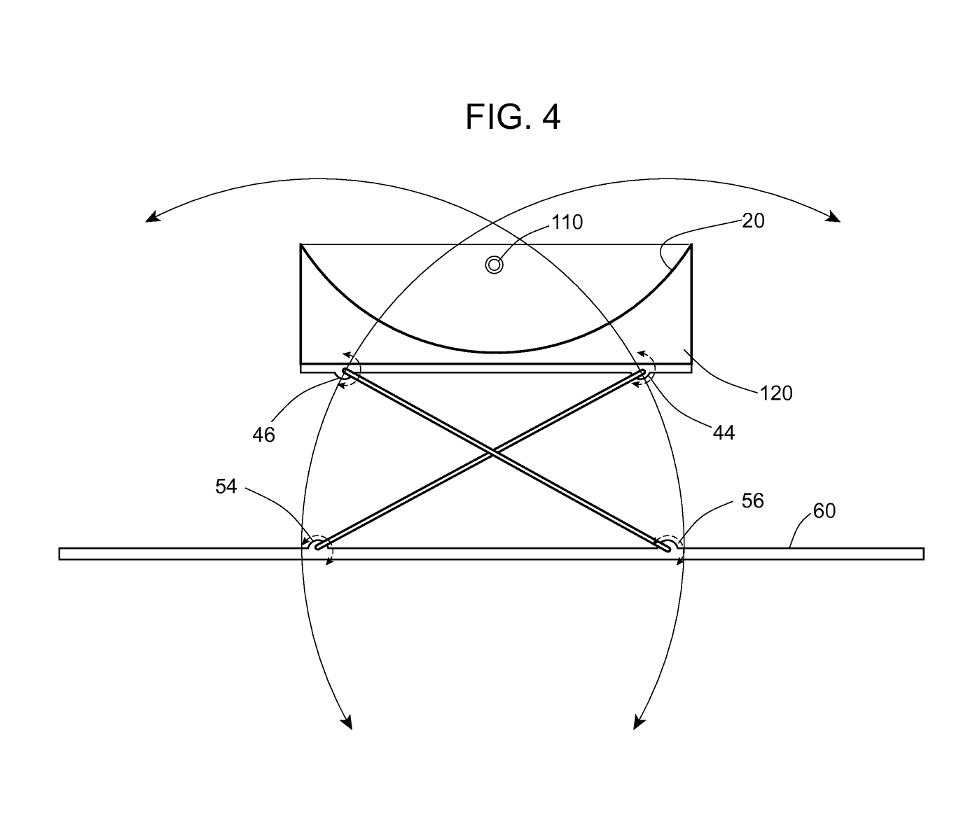

In FIG. 1, the tracking apparatus 10 of the invention is described in connection with arrays of photovoltaic cells, or “solar panels” 30. One or more such panels 30 form a collector surface 20. The invention is not limited as to the type of panels used. For example, one or more Sharp USA monocrystalline photovoltaic array Model No. NU245W2 panels may be adapted with minimal modification for this purpose to form collector surface 20. In the embodiment depicted, the collector surface has parallel opposed side edges 12 and 14 on the north and south sides of the apparatus. The collector surface according to the invention need not be flat, and need not be an active photovoltaic surface. For example, the collector may be a parabolic passive solar collector such as disclosed in the aforesaid U.S. Pat. No. 8,069,849. This embodiment is depicted schematically in FIG. 4, wherein the surface 20 of the parabolic collector 120 is focused on a receiver element 110 carrying a heat transfer fluid. As used herein, any such surface is a “collector surface.”

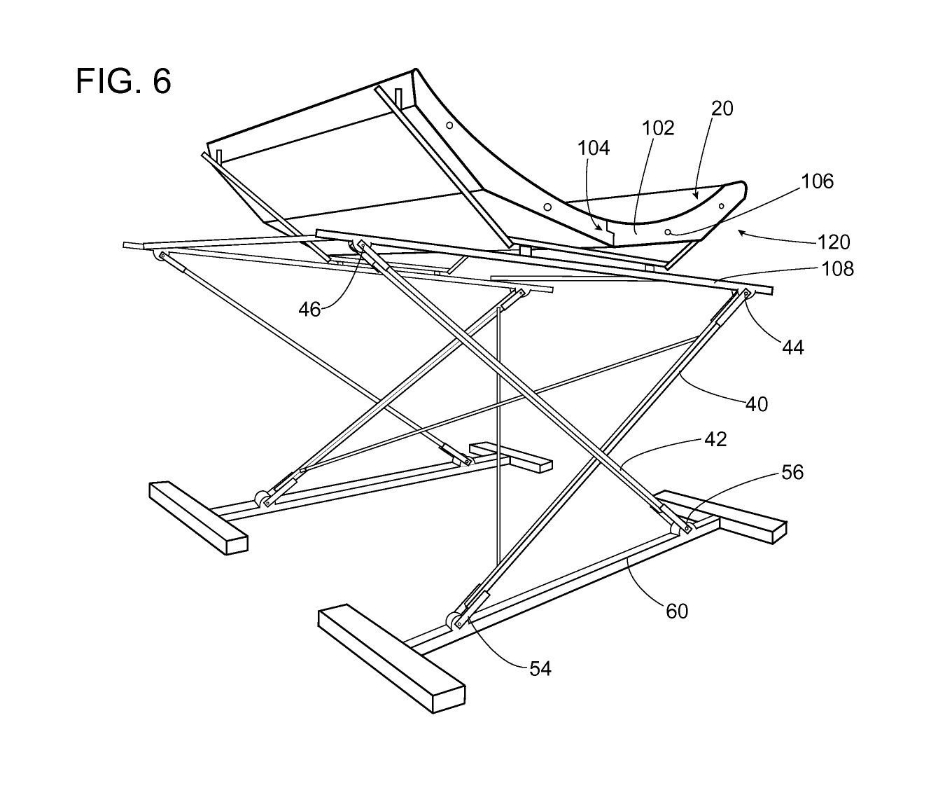

As shown in FIG. 1, the collector surface 20 is positioned facing upward toward the sun. Elongated struts 40, 42 are attached to the collector surface at respective pivot points 44, 46 and arranged to move the panel in an arc from east to west. To accomplish this movement in an arc, the struts are connected at opposed sides of the collector 12, 14. Within the scope of the invention, the struts may be attached proximate the sides, such as on the rear of the panel near the side edges, or on an upper frame 108 proximate the sides of the collector surface (shown in FIG. 6), and not directly on the side edges. The construction of the pivot points is not particularly limited according to the invention, although it is preferred that the pivot points are biased or “stiff” so that a predetermined force must be applied to the struts before any movement occurs. Preferably a predetermined force of 5 lbs to 50 lbs, and more preferably 10 lbs to 20 lbs must be exerted to cause movement of the struts. The exact configuration of the connectors at the pivot points is not critical. The force needed to move the tracker through its range of motion can be calculated based on the weight of the collector; a linear motor 80 having a rated push load of 50,000 N and a rated pull load of 50,000 N is sufficient for most purposes.

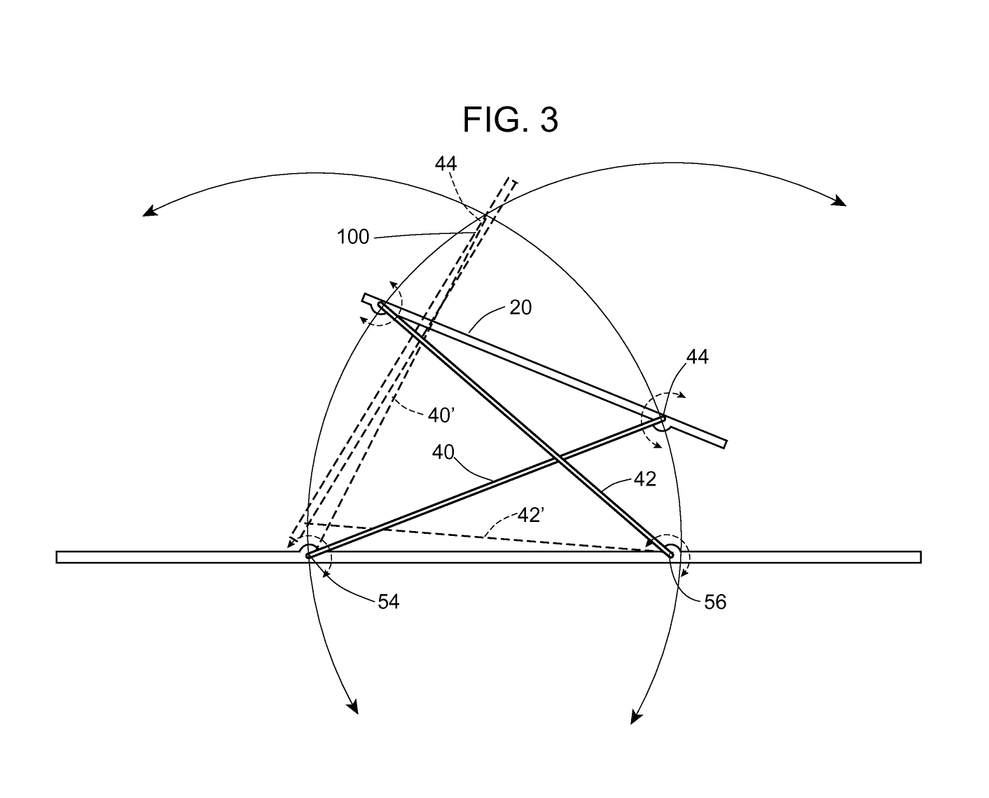

The attachment of the struts 40, 42 to the collector surface 20 allows the collector surface to pivot about the pivot points 44, 46, while such motion is constrained by the attachment of the collector surface to the other pivot points and to the base connectors 54, 56. Preferably, the pivot points permit the struts to move only in one plane, for example parallel to the side edges 12, 14, east to west, without substantial north-to-south movement. “Without substantial movement” means that such movement is avoided to the extent feasible with ordinary mechanical equipment. In the embodiment shown in FIG. 1, steel cross brace members 94 connect the struts to stiffen the apparatus and prevent north-to-south movement. The pivot point connectors should permit freedom of motion for each strut, generally as close as possible to 90 degrees, as shown in FIG. 3. For example, the pivot point and the strut may be attached via a shaft on either the strut or the pivot point connector passing through the hole on the opposite member, (i.e., a journalled connection). In actual operation, the struts will generally have a range of motion less than 90 degrees, depending on how the struts are attached to the collector. The struts are conveniently made of any suitably strong and rigid material, such as steel, aluminum, PVC, or the like. An apparatus such as shown in FIG. 1 is conveniently constructed on a 6′×6′ square base, with a height of 5′, and may be supported with square or round tubes having an outer diameter in a range of ½″ to 2″, although these dimensions are not critical.

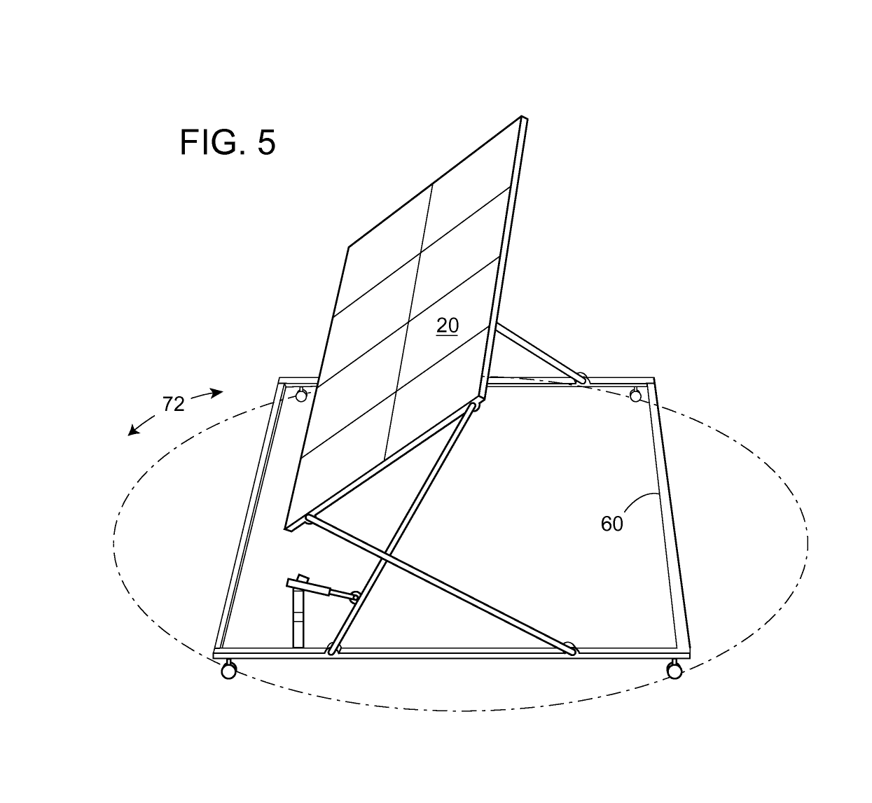

Each strut is attached at its opposite end in a pivoting relationship with a respective fixed base connector 54, 56. The base connectors are secured directly to the earth, or on a base or frame 60. The base connectors 54 and 56 are fixed in the sense that they do not translate vertically or translate relative to frame 60. In embodiments, particularly when the collector is a parabolic dish, the base frame 60 in FIG. 5 may be rotated about a vertical axis in the directions indicated by double-headed arrow 72 to permit two axis tracking. In this case, the drive system includes at least a second motor (not shown) to rotate the frame 60 about a vertical axis, further enhancing the ability to track the sun in different seasons and at different times throughout the day.

The struts on each side of the collector surface cross at 70. In embodiments, opposed bearing surfaces may be provided on the struts allowing for sliding contact of the two struts against one another where they cross. The pivot points are preferably on the opposed north and south sides of the collector surface 20, such that pivot point connector 44, which is farther to the east, connects to a base connector 54 on the same side of the collector surface which is farther to the west. As with the pivot point connectors, the base connectors permit the struts to rotate as far as 90 degrees, if possible, and the same type of connection may be used. As seen in FIG. 3, the actual freedom of motion of the struts, both at the base connector and at the pivot points, is somewhat less than 90 degrees.

A drive system comprises at least one motor 80 adapted to pivot a strut about a base connector. Of course, moving one strut moves all of the struts about the respective pivot point connectors and base connectors, because all of the struts are connected to the collector surface 20.

In the embodiment of FIG. 1, a cable 82 is threaded around pulleys 84 and 86 and also about the pivot points 44 and 46. The cable may be, for example, ¼-inch or ½-inch stainless steel cable. The cable is connected to the motor 80 to pivot the struts.

The motor is advantageously connected to a computer control which determines the movement of the collector surface. A suitable motor is an SKF model SLS 500020 linear motor with a rated push load of 50000 N and a rated pull load of 50000 N and a stroke of 100 mm to 700 mm.

A computerized controller to control the motor may be programmed based on input from an optical sensor such that nightfall causes the motor to park the collector surface in the east-facing direction, daylight signals the motor to commence operation, and the collector surface is moved throughout the day to maintain the intensity of light measured at the sensor at a maximum. Where it is desired to use the apparatus according to the invention with a parabolic dish collector, it is preferred to use a second motor to rotate the base, as shown in FIG. 5, while at least one first motor controls the inclination angle of the collector. Rotation about an axis may be based on a timer rather than subject to a control based on measured conditions.

As used herein, “horizontal” is with respect to the apparatus. Thus, “horizontal” means a plane formed by base connectors 54, 56, and 58. Base connectors 54, 56, and 58 may be attached directly to the earth or to a base frame 60, which frame can then be conveniently mounted on another structure such as a building roof, which may be level or slanted. Providing a frame permits a mobile installation and allows greater flexibility in mounting. In a simple embodiment, a base frame comprises four elongated members forming a rectangular shape with sides generally corresponding to the sides of the collector as shown in FIG. 5. An important advantage of the tracking apparatus according to the invention is the ease with which the support structure can be made modular and portable. Thus, in embodiments, the base frame, upper frame (where applicable), and struts can be provided as tubular lengths adapted to be transported separately and assembled on site.

Solar panels 30 are generally provided with circuitry to convert the variable DC current produced by the panels to constant AC current, which may then be used to drive loads on site, or stored in batteries. Conductors (not shown) may conveniently be provided inside the struts to withdraw usable electric current from the apparatus.

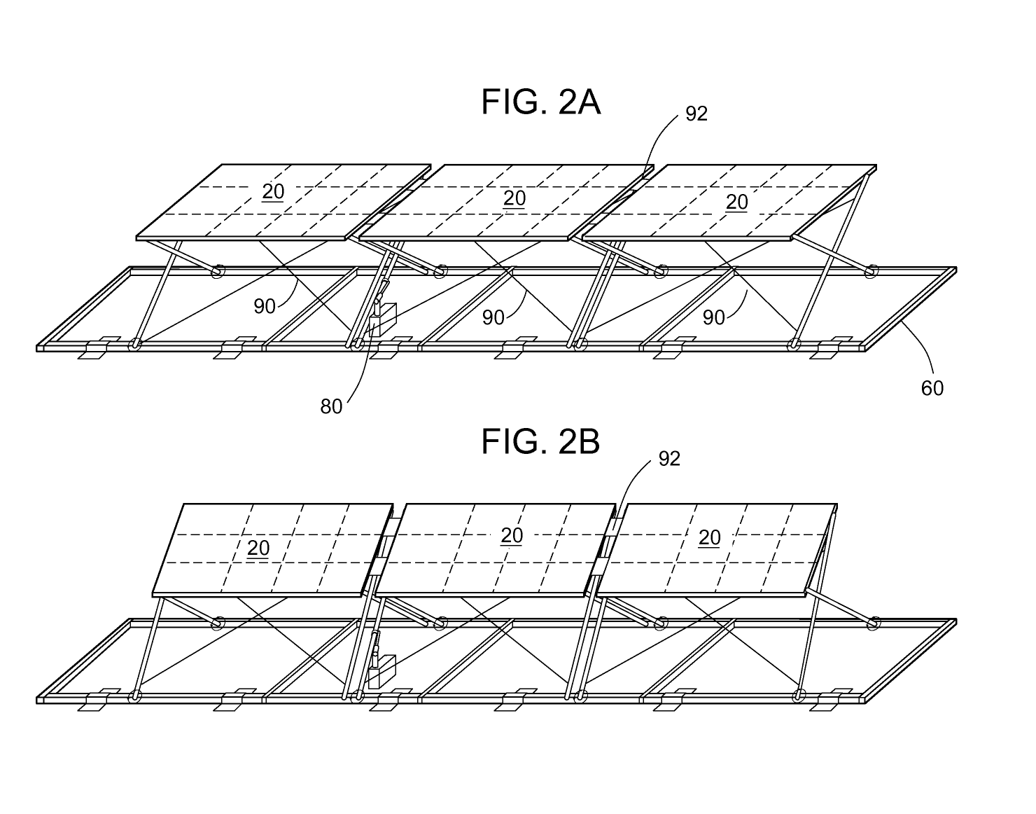

In the embodiment shown in FIG. 2A and FIG. 2B, several tracking apparatuses are connected in an array, and a single motor 80 controls the inclination angle of the plurality of collector surfaces 20. Guy members, such as rods or cables 90, may be provided cross-wise from north to south to secure the tracking apparatus from side to side motion in a wind. Stiffening units 92 connect the individual units of the array, ensuring that the collector surfaces 20 all move together. Guy rods or cables 90 perform the same or similar function as cross braces 94 in FIG. 1.

### EXAMPLES

In an embodiment constructed according to FIG. 6, a plurality of foam base segments 102 were fitted together in interlocking fashion at seam(s) 104 to form a focusing collector surface 20. Cutting of expanded polystyrene (EPS) foam blocks using computer numerical control (CNC) to form the foam vase segments was performed substantially as described in U.S. Pat. No. 8,069,849 to ensure a calibrated collector surface. Alignment rods 106 are positioned inside the foam base segments 102 and facilitate the alignment of the segments longitudinally. In the embodiment of FIG. 6, the pivot points are located proximate the opposed sides of the collector surface and attached to the foam base segments 102 via an upper frame 108. In the embodiment shown, the base frame 60 was comprised of straight steel members parallel to the sides of the collector and having a larger size and heavier gauge than the struts. Attachment of the base frame 60 to a surface such as a roof would be well within the skill of the ordinary worker in the art. In the embodiment shown, the base frame members were made of straight lengths of 1½″ square steel tubing, while the struts were ¾ square steel tubing, although the dimensions of the framing are not critical.

In an embodiment constructed according to FIG. 1, struts 40 and 42 were made with the same square steel tubing as in the previous example. Sharp USA monocrystalline photovoltaic panels 30 were welded together to form collector surface 20, although any number of commercially available photovoltaic panels might be suitable for this purpose. The opposed ends of the struts formed journaled connections at pivot point connectors 44, 46, attached proximate the side edges 12, 14 of the collector surface, and similar connections were formed between the struts and the base connectors 54, 56.

FIG. 3 depicts the range of motion of an apparatus constructed according to the embodiment of FIG. 1. The dotted outline 100 shows the position of collector surface in a first position, when first strut 40 (in position 40′ at this stage) is nearly as close to vertical as the fixed position of the base connectors 54, 56 will allow. At the start of the day, responsive to signals from a control unit (not shown) an SKF model SLS 500020 linear motor 80 drives a connected strut to realize the collector surface in this position. As the sun moves across the sky, responsive to further signals from the control unit, motor 80 imparts motion to strut 40 so that it moves from position 40′ to the position in FIG. 3, which is shown in solid outline.

Motor 80 may be used to drive a cable threaded in a loop around pulleys at the pivot points and at the base connectors, to impart east-to-west motion of the struts.

The foregoing description of the preferred embodiments should not be deemed to limit the claimed invention, which is defined by the appended claims.

What is claimed is:

1. A solar tracking apparatus, comprising:
a collector having an upward-facing surface and opposed sides;
at least two pivot points proximate each of the opposed sides;
base connectors equal in number to the number of pivot points, all of said base connectors being in a fixed plane and at a fixed position relative to the other base connectors;
elongated struts, equal in number to the pivot points, each strut having opposed first and second ends, each said first end being connected to a pivot point connector at a pivot point, and each said second end being connected to a base connector;
wherein each said pivot point connector permits rotation of each respective connected strut about the respective pivot point, and each said base connector permits rotation of each respective connected strut about the respective base connector;
wherein two struts connecting pivot point connectors and base connectors on each respective side of the collector surface cross; and
at least one drive system operatively connected to at least one strut and adapted to pivot said strut connected to the drive system to vary an inclination angle of the collector surface with respect to the horizontal.

2. The apparatus according to claim 1, wherein the collector surface is a substantially flat photovoltaic panel, and the opposed sides of the photovoltaic panel are parallel.

3. The apparatus according to claim 1, wherein the collector surface is parabolic.

4. The apparatus according to claim 1, wherein the collector comprises at least one foam segment forming a parabolic trough, said foam segment having a reflective surface thereon.

5. The apparatus according to claim 4, wherein said at least one foam segment is supported in an upper frame, and said pivot points are located on said upper frame proximate the sides of the collector.

6. The apparatus according to claim 4, comprising a plurality of foam segments joined to form a parabolic trough.

7. The apparatus according to claim 1, wherein the drive system comprises a cable threaded around pulleys at the pivot points and the base connectors and connected to the motor to rotate the struts when the motor drives the cable.

8. The apparatus according to claim 1, further comprising a base frame connecting each of the base connectors in a plane and having sides corresponding to the opposed sides of the collector.

9. The apparatus according to claim 4, wherein the base frame comprises four or more elongated members forming a closed shape, adapted to be mounted on a building roof.

10. The apparatus according to claim 1, further comprising a plurality of guy members attached to struts at opposite sides of the base frame.

11. The apparatus according to claim 2, further comprising conductive members located in one or more struts for carrying electric current produced by the photovoltaic panel.

12. The apparatus according to claim 1, wherein the opposed sides of the collector surface are on the north and south sides of the collector surface and the struts rotate the collector surface in an east-to-west direction.

13. The apparatus according to claim 1, wherein the base connectors are provided on a base, and further comprising at least one second motor adapted to rotate the base about a vertical axis.

14. The apparatus according to claim 1, wherein the base connectors are adapted to be mounted in the earth.

15. The apparatus according to claim 1, wherein the drive system is further operatively connected to a second solar tracking apparatus, so that one drive system controls the inclination angle of a second solar tracking device.

16. The apparatus according to claim 1, wherein the collector surface comprises a plurality of photovoltaic panels connected to form a flat collector surface having parallel side edges on the north and south side of the apparatus and the pivot point connectors are attached to the north and south side edges of the collector surface.
